(19) United States
(12) Patent Application Publication
(10) Pub. No.: US 2022/0127495 A1
(43) Pub. Date: Apr. 28, 2022

(54) POLISHING SLURRY COMPOSITION

(71) Applicant: KCTECH CO., LTD., Gyeonggi-do (KR)

(72) Inventors: Jin Sook HWANG, Gyeonggi-do (KR); Hyun Goo KONG, Gyeonggi-do (KR); Eun Jin LEE, Gyeonggi-do (KR)

(73) Assignee: KCTECH CO., LTD., Gyeonggi-do (KR)

(21) Appl. No.: 17/511,582

(22) Filed: Oct. 27, 2021

(30) Foreign Application Priority Data
Oct. 28, 2020 (KR) 10-2020-0141358

(51) Int. Cl. C09G 1/02; C09K 3/14

(52) U.S. Cl. CPC C09G 1/02; H01L 21/304; C09K 3/1454

(57) ABSTRACT

A polishing slurry composition is provided. The polishing slurry composition includes abrasive particles, an oxidizer, an iron-containing catalyst, and a stabilizer, and a retention rate of the oxidizer according to Equation 1 is 70% or greater.

Retention rate (%) of oxidizer=(concentration (%) of oxidizer after 7 days at room temperature×100)/(initial concentration (%) of oxidizer in polishing slurry composition) [Equation 1]

### CROSS-REFERENCE TO RELATED APPLICATION

This application claims the benefit of Korean Patent Application No. 10-2020-0141358 filed on Oct. 28, 2020, in the Korean Intellectual Property Office, the entire disclosure of which is incorporated herein by reference for all purposes.

### BACKGROUND

### 1. Field of the Invention

One or more example embodiments relate to a polishing slurry composition, and more particularly, to a slurry composition for polishing a metal film.

### 2. Description of the Related Art

A chemical mechanical polishing (CMP) process refers to a process of contacting a surface of a semiconductor wafer with a polishing pad and smoothly performing polishing using a slurry containing an abrasive and various compounds during a rotation movement. In general, it is known that a metal polishing process occurs as a process of formation of a metal oxide (MOₓ) by an oxidizer and a process of removal of the formed metal oxide by abrasive particles are repeated.

A polishing process of a tungsten layer frequently used as a wiring of a semiconductor device is also performed via a mechanism in which a process of formation of tungsten oxide (WO₃) by an oxidizer and a potential regulator and a process of removal of the tungsten oxide by abrasive particles are repeated. In addition, an insulating layer or such patterns as trenches, etc. may be formed below the tungsten layer. In this case, high polishing selectivity is required for the tungsten layer and the insulating layer, and the polishing process occurs continuously. If the selectivity of the slurry is too high, recess may occur on the target layer due to excessive polishing, or the erosion of an insulating layer or a barrier layer by the physical action of abrasive particles may be aggravated. Recess and erosion phenomena may act as defects during global planarization of a wafer, and device defect may occur as the defects are accumulated due to stacking. Although there have been attempts to control polishing selectivity and achieve polishing performance by adding catalysts or various other components in the slurry, there is a difficulty in achieving a constant polishing rate during a continuous process due to rapid oxidation-reduction reactions.

### SUMMARY

Example embodiments provide a polishing slurry composition that may ensure process reproducibility in a continuous polishing process while achieving desired polishing performance (e.g., a polishing rate).

However, the problem to be solved by the present disclosure is not limited to that described above, and other unmentioned problems may be clearly understood by those having ordinary knowledge in the art from the following description.

According to an aspect, there is provided a polishing slurry composition including abrasive particles, an oxidizer, an iron-containing catalyst, and a stabilizer, wherein a retention rate of the oxidizer according to Equation 1 is 70% or greater.

Retention rate (%) of oxidizer=(concentration (%) of oxidizer after 7 days at room temperature×100)/(initial concentration (%) of oxidizer in polishing slurry composition) [Equation 1]

A molar ratio of the stabilizer to the iron-containing catalyst may be from 5:1 to 200:1.

The polishing slurry composition may satisfy Equation 2.

99.8−2186×(amount (% by weight (wt %)) of iron-containing catalyst in polishing slurry composition)+158×(amount (wt %) of stabilizer in polishing slurry composition)>70 [Equation 2]

The iron-containing catalyst may be included in an amount of 0.0001 wt % to 1 wt % in the polishing slurry composition.

The iron-containing catalyst may include an iron(II) compound, an iron(I) compound or both, and the iron-containing catalyst may include at least one of iron nitrate, iron sulfate, iron halide, iron perchlorate, iron acetate, iron acetylacetonate, iron gluconate, iron oxalate, iron phthalate and iron succinate.

The stabilizer may include an organic acid, and the organic acid may include at least one of citric acid, malic acid, maleic acid, malonic acid, oxalic acid, succinic acid, lactic acid, tartaric acid, adipic acid, pimelic acid, suberic acid, azelaic acid, sebacic acid, fumaric acid, acetic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, valeric acid and ascorbic acid.

The stabilizer may be included in an amount of 0.0001 wt % to 1 wt % in the polishing slurry composition.

The abrasive particles may include at least one of a metal oxide, a metal oxide coated with an organic material or an inorganic material and a metal oxide in a colloidal phase, and the metal oxide may include at least one of silica, ceria, zirconia, alumina, titania, barium titania, germania, mangania and magnesia.

The abrasive particles may include single-sized particles with a size of 10 nanometers (nm) to 200 nm, or a mixture of two or more particles with different sizes of 10 nm to 200 nm.

The abrasive particles may be included in an amount of 0.0001 wt % to 10 wt % in the polishing slurry composition.

The oxidizer may include at least one of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate, dipersulfate and sodium peroxide.

The oxidizer may be included in an amount of 0.0001 wt % to 5 wt % in the polishing slurry composition.

A polishing target film of the polishing slurry composition may be a metal film, and the metal film may include at least one of a metal, a metal nitride, a metal oxide and a metal alloy.

Each of the metal, the metal nitride, the metal oxide and the metal alloy may include at least one of indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru) and tungsten (W).

The polishing slurry composition may further contain a polishing inhibitor, and the polishing inhibitor may be included in an amount of 0.0001 wt % to 1 wt % in the polishing slurry composition.

The polishing inhibitor may include at least one of glycine, histidine, alanine, serine, phenylalanine, threonine, valine, leucine, isoleucine, proline, lysine, arginine, aspartic acid, tryptophan, betaine, cocamidopropyl betaine, lauryl propyl betaine, methionine, cysteine, glutamine and tyrosine.

pH of the polishing slurry composition may be in a range from 1 to 12.

A polishing speed of the polishing slurry composition for a polishing target film may be 500 Å/min or greater.

A decomposition rate of the oxidizer according to Equation 3 may be 10% or less.

Decomposition rate of oxidizer=(initial concentration (%) of oxidizer in polishing slurry composition−concentration (%) of oxidizer after 7 days at room temperature)×100/(initial concentration (%) of oxidizer in polishing slurry composition) [Equation 3]

Additional aspects of example embodiments will be set forth in part in the description which follows and, in part, will be apparent from the description, or may be learned by practice of the disclosure.

According to example embodiments, a polishing slurry composition may have improved stability of an oxidizer with a retention rate of 70% or greater and/or a decomposition rate of 10% or less after being left alone at room temperature for a predetermined period of time.

According to example embodiments, a polishing slurry composition may ensure predetermined polishing reproducibility in a continuous polishing process while achieving desired polishing performance (e.g., a polishing rate) for a polishing target film and may improve patterning characteristics (e.g., recess or protrusion) of the polishing target film.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates a retention rate (%) of hydrogen peroxide in polishing slurry compositions of examples and comparative examples depending on a molar ratio of a stabilizer and an iron-containing catalyst according to an example embodiment;

FIG. 2 illustrates a depth of recesses formed after a polishing process using polishing slurry compositions of examples and comparative examples according to an example embodiment; and

FIG. 3 illustrates a retention rate (%) of hydrogen peroxide in polishing slurry compositions of examples and comparative examples according to an example embodiment.

### DETAILED DESCRIPTION

Hereinafter, example embodiments of the present disclosure will be described in detail with reference to accompanying drawings. When describing the present disclosure, detailed description of related known functions or configurations will be omitted if it is identified that it may unnecessarily obscure the gist of the present disclosure. In addition, the terms used in the present specification are used to adequately describe specific example embodiments of the present disclosure, and may be changed according to the intent of users or operators, the practices of the field to which the present disclosure belongs, etc. Accordingly, definitions of the terms should be understood on the basis of the entire description of the present specification. In the drawings, like numerals refer to like elements.

Throughout the specification, when a member is said to be positioned “on” another member, this includes not only a case where the member is in contact with the other member but also a case where another member exists between the two members.

Throughout the specification, when a certain portion “includes” a certain component, it means that other components may be further included rather than being excluded unless specifically stated to the contrary.

Hereinafter, a polishing slurry composition according to the present disclosure will be described in detail through example embodiments and drawings. However, the present disclosure is not limited by the example embodiments and drawings.

The present disclosure relates to a polishing slurry composition. According to an example embodiment, the polishing slurry composition may include abrasive particles, an oxidizer, an iron-containing catalyst, and a stabilizer, and may further include at least one of a polishing inhibitor, a pH control agent, and a biocide.

In an example embodiment, the abrasive particles may include at least one of a metal oxide, a metal oxide coated with an organic material or an inorganic material and a metal oxide in a colloidal phase, and the metal oxide may include at least one of silica, ceria, zirconia, alumina, titania, Barium titanate, germania, mangania and magnesia.

For example, the abrasive particles may have at least one of spherical, square, needle and plate shapes.

For example, the abrasive particles may include particles with a size of 10 nanometers (nm) to 200 nm, or 20 nm to 200 nm. When the size of the abrasive particles is included in the above range, desired polishing rate may be ensured and overpolishing due to increased size may be prevented. For example, the abrasive particles may include single-sized particles with a size of 10 nm to 200 nm or a mixture of two or more particles with different sizes of 10 nm to 200 nm. For example, the abrasive particles may include first particles with a size of 10 nm to 50 nm and second particles with a size in the range of greater than 50 nm to 100 nm, and the mixing ratio (mass ratio) of the first particles to the second particles may be 1:0.1 to 10. The size may refer to diameter, length, thickness, etc. depending on the shape of the particles.

For example, the abrasive particles may include particles with a single specific surface area of 30 to 150 m²/g or a mixture of two or more particles with different specific surface areas of 30 to 150 m²/g. For example, the abrasive particles may include first particles with a specific surface area of 30 to 80 m²/g and second particles with a specific surface area in the range of greater than 80 to 150 m²/g, and the mixing ratio (mass ratio) of the first particles to the second particles may be 1:0.1 to 10.

For example, the abrasive particles may be included in an amount of 0.0001 wt % to 20 wt %, 0.0001 wt % to 10 wt %, or 0.1 wt % to 10 wt % in the polishing slurry composition. When the amount of the abrasive particles is included within the above range, it is possible to achieve a desired polishing rate according to a polishing target film (e.g., a metal film) and/or desired selectivity through control of a polishing rate, to reduce the number of abrasive particles remaining on the surface of the polishing target film (e.g., a metal film) caused by an increase in the amount of the abrasive particles, and prevent secondary defects such as recess or erosion from occurring in a pattern due to decreased polishing speed and overpolishing owing to a small amount of the abrasive particles.

In an example embodiment, the oxidizer may improve stability in the polishing slurry composition and maintain constant polishing performance of the polishing slurry composition.

For example, a retention rate of the oxidizer according to Equation 1 may be 70% or greater and/or a decomposition rate (%) of the oxidizer according to Equation 3 may be 10% or less. When the retention rate and/or the decomposition rate are/is included in the above range(s), the desired polishing rate may be ensured and the reproducibility of polishing performance may be ensured in a continuous polishing process.

Retention rate (%) of oxidizer=(concentration (%) of oxidizer after 7 days at room temperature×100)/(initial concentration (%) of oxidizer in polishing slurry composition) [Equation 1]

Decomposition rate of oxidizer=(initial concentration (%) of oxidizer in polishing slurry composition−concentration (%) of oxidizer after 7 days at room temperature)×100/(initial concentration (%) of oxidizer in polishing slurry composition) [Equation 3]

In Equations 1 and 3, the initial concentration (%) is the initial concentration after the addition of the oxidizer to the polishing slurry composition. For example, the values of the parameters in Equation 1 and Equation 3 are measured after storage at room temperature (rt) for 7 days (e.g., in a sealed brown vial (100 mL), with relative humidity maintained at 40% to 70%).

In an example embodiment, the polishing slurry composition may satisfy Equation 2.

99.8−2186×(amount (% by weight (wt %)) of iron-containing catalyst in polishing slurry composition)+158×(amount (wt %) of stabilizer in polishing slurry composition)>70 [Equation 2]

For example, a molar ratio of the stabilizer to the iron-containing catalyst may be from 5:1 to 200:1, from 8:1 to 200:1, from 10:1 to 200:1, from 11:1 to 200:1 or from 15:1 to 150:1. When the molar ratio is included within the ranges, desired polishing performance such as the polishing rate of a polishing target film, etc. may be ensured and the stability of the oxidizer may be improved.

That is to say, by using a slurry composition wherein the amounts of the iron-containing catalyst and the stabilizer satisfy Equation 2 and the molar ratio of the iron-containing catalyst to the stabilizer is 5 or greater, the retention rate of the oxidizer after 7 days at room temperature may be 70% or greater or the decomposition rate of the oxidizer may be 10% or less. Through this, the desired polishing rate may be achieved as tungsten oxide is formed easily by an OH radical generated by the decomposition of hydrogen peroxide and superior patterning characteristics (recess or protrusion) may be achieved during a continuous process due to ensured polishing reproducibility.

For example, the oxidizer may be at least one of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate, dipersulfate and sodium peroxide.

For example, the oxidizer may be included in an amount of 0.0001 wt % to 5 wt %, 0.01 wt % to 3 wt %, or 0.1 wt % to 3 wt % in the polishing slurry composition. When the amount of the oxidizer is included in the above range, it is possible to achieve polishing speed and polishing performance adequate for a polishing target film, prevent overpolishing caused by an increase in the amount of the oxidizer, and prevent corrosion, erosion and surface hardening of the polishing target film.

In an example embodiment, the stabilizer may prevent the retention of impurities such as metal ions and particles in a polishing process, ensure the dispersion stability of abrasive particles, improve or prevent deterioration of the stability of the oxidizer in the polishing slurry composition, and achieve constant reproducibility in a continuous process using the polishing slurry composition.

For example, the stabilizer may include an organic acid, and the organic acid may include at least one of citric acid, malic acid, maleic acid, malonic acid, oxalic acid, succinic acid, lactic acid, tartaric acid, adipic acid, pimelic acid, suberic acid, azelaic acid, sebacic acid, fumaric acid, acetic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, valeric acid and ascorbic acid.

For example, the stabilizer may be included in an amount of 0.0001 wt % to 1 wt %, 0.01 wt % to 1 wt %, or 0.01 wt % to 0.5 wt % in the polishing slurry composition. When the amount of the stabilizer is included in the above range, it is possible to prevent deterioration of the stability of the oxidizer, achieve desired polishing characteristics, and prevent an increase in corrosion of a polishing target film (e.g., a metal film) and a decrease in the particle dispersion stability of the polishing slurry composition.

In an example embodiment, the polishing inhibitor (amphoteric compound) may be for controlling the dispersion stability and selectivity of the slurry composition. For example, the polishing inhibitor may include at least one of glycine, histidine, alanine, serine, phenylalanine, threonine, valine, leucine, isoleucine, proline, lysine, arginine, aspartic acid, tryptophan, betaine, cocamidopropyl betaine, lauryl propyl betaine, methionine, cysteine, glutamine and tyrosine.

For example, the polishing inhibitor may be included in an amount of 0.0001 wt % to 1 wt % in the polishing slurry composition. When the amount of the polishing inhibitor is included in the above range, it is possible to achieve controlled selectivity and improved polishing performance.

In an example embodiment, the iron-containing catalyst may include an iron(II) compound, an iron(I) compound or both, and the iron-containing catalyst may include at least one of iron nitrate, iron sulfate, iron halide, iron perchlorate, iron acetate, iron acetylacetonate, iron gluconate, iron oxalate, iron phthalate and iron succinate.

For example, the iron-containing catalyst may be included in an amount of 0.0001 wt % to 1 wt %, 0.005 wt % to 1 wt % or 0.005 wt % to 0.1 wt % in the polishing slurry composition. When the amount of the iron-containing catalyst is included in the above range, it is possible to ensure polishing performance such as a desired polishing rate for a polishing target film, etc. and to improve the storage stability of a polishing slurry composition.

In an example embodiment, the pH control agent may be for preventing corrosion of a polishing target film, e.g., a metal film, or a polisher and achieving a pH range suitable for polishing performance. The pH control agent may include an acidic material or an alkaline material. The acidic material may include at least one of nitric acid, hydrochloric acid, phosphoric acid, sulfuric acid, hydrofluoric acid, bromic acid, iodic acid, formic acid, malonic acid, maleic acid, oxalic acid, acetic acid, adipic acid, citric acid, adipic acid, propionic acid, fumaric acid, lactic acid, salicylic acid, pimelic acid, benzoic acid, succinic acid, phthalic acid, butyric acid, glutaric acid, glutamic acid, glycolic acid, lactic acid, asparagic acid, tartaric acid and salts thereof, and the alkaline material may include at least one of ammonium methyl propanol (AMP), tetramethyl ammonium hydroxide (TMAH), ammonium hydroxide, potassium hydroxide, sodium hydroxide, magnesium hydroxide, rubidium hydroxide, cesium hydroxide, sodium bicarbonate, sodium carbonate, imidazole and salts thereof.

In an example embodiment, the biocide may be for controlling biological growth of bacteria, fungi, etc. during the storage of the polishing slurry composition. The biocide may include at least one of methylisothiazolinone, methylchloroisothiazolinone, tetramethylammonium chloride, tetraethylammonium chloride, tetrapropylammonium chloride, alkylbenzyldimethylammonium chloride or alkylbenzyldimethylammonium hydroxide (wherein the alkyl chain contains about 1 to 20 carbon atoms), chlorine-containing compounds (e.g., sodium chlorite and sodium hypochlorite), biguanide, aldehydes, ethylene oxide, metal salts, isothiazolinone, tetrakis(hydroxymethyl)phosphonium sulfate (THPS), 1,3,5-tris(2-hydroxyethyl)-s-triazine, iodopropynyl butylcarbamate, 1,2-benzisothiazolin-3-one, 4,4-dimethyloxazolidine, 7-ethylbicylclooxazolidine, a mixture of 4-(2-nitrobutyl)morpholine and 4,4′-(2-ethyl-2-nitrotrimethylene)dimorpholine, 2-methyl-4-isothiazolin-3-one, a mixture of 5-chloro-2-methyl-4-isothiazolin-3-one and 2-methyl-4-isothiazolin-3-one, 2-bromo-2-nitro-1,3-propanediol, octylisothiazolinone, dichlorooctylisothiazolinone, dibromooctylisothiazolinone, phenols (e.g., o-phenylphenol, p-chloro-m-cresol and sodium and/or potassium salts thereof), sodium pyrithione, zinc pyrithione, n-butylbenzisothiazolinone, 1-(3-chloroallyl)-3,5,7-triaza-1-azoniaadamantane chloride, chlorothalonil, carbendazim, diiodomethyltolylsulfone, trimethyl-1,3,5-triazine-1,3,5-triethanol, 2,2-dibromo-3-nitrilopropionamide, glutaraldehyde, N,N′-methylene-bis-morpholine, ethylenedioxymethanol, phenoxyethanol, tetramethylol acetylenediurea, dithiocarbamate, 2,6-dimethyl-m-dioxan-4-ol acetate, dimethylol dimethyl hydantoin, tris(hydroxymethyl)nitromethane and bicyclic oxazolidine.

For example, the biocide may be included in an amount of 0.0001 wt % to 0.10 wt % in the polishing slurry composition.

In an example embodiment, the pH of the polishing slurry composition may be in a range from 1 to 12, from 1 to 8, or from 2 to 7. An acidic range may be desirable for the dispersion stability and polishing performance of the slurry composition.

In an example embodiment, a polishing target film of the polishing slurry composition may be a metal film, and the metal film may include at least one of a metal, a metal nitride, a metal oxide and a metal alloy. The polishing slurry composition may be applied to a chemical mechanical polishing (CMP) process of a substrate including a metal film as a polishing target film.

For example, the metal film may include at least one of a metal, a metal nitride, a metal oxide and a metal alloy, and each of the metal, the metal nitride, the metal oxide and the metal alloy may include at least one of indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru) and tungsten (W). Specifically, the metal film may be a tungsten metal film.

In an example embodiment, a polishing speed of the polishing slurry composition for a polishing target film may be, for example, 500 Å/min or greater, or 1000 Å/min to 4000 Å/min, and a polishing selectivity, i.e. the ratio of the polishing speed for the metal film to the polishing speed for, e.g., an oxide film may be 20 or greater.

In an example embodiment, the polishing slurry composition may realize desired polishing performance and improve planarization and patterning characteristics by preventing phenomena (recess and/or protrusion) occurring after a polishing process. For example, in a substrate including a film patterned with the polishing slurry composition, a depth of recesses on the patterned surface of the substrate after the polishing process (e.g., after polishing of a bulk metal film) may be 150 Å or less, 120 Å or less or 100 Å or less.

Hereinafter, the present disclosure is described in more detail through examples. However, the following examples are for illustrative purposes only, and the scope of the present disclosure is not limited thereto.

### (1) Examples 1 to 6

Polishing slurry compositions were prepared according to Table 1 by adding colloidal silica (size: 20 nm to 200 nm), hydrogen peroxide, iron nitrate, malonic acid and glycine and using nitric acid as a pH control agent.

### (2) Comparative Examples 1 to 5

Polishing slurry compositions were prepared according to Table 1 by adding colloidal silica (size: 20 nm to 200 nm), hydrogen peroxide, iron nitrate, malonic acid and glycine and using nitric acid as a pH control agent.

Molar ratios of the malonic acid (stabilizer) to the iron nitrate (catalyst) in the polishing slurry compositions of Examples 1 to 6 and Comparative Examples 1 to 5 were calculated according to the following equation and the results are shown in Table 1.

Molar ratio(B/A)=(moles of stabilizer(B)added)/(moles of catalyst(A)added)

(stabilizer=malonic acid, catalyst=iron nitrate)

TABLE 1

| | | | Catalyst | Stabilizer | Oxidizer | | | | |
|---|---|---|---|---|---|---|---|---|---|
| | | | (A) | (B) | (C) | | | | Molar |
| | | | Iron | Malonic | Hydrogen | Polishing | | | ratio |
| | Particles | wt % | nitrate (%) | acid (%) | peroxide (%) | inhibitor | wt % | pH | (B/A) |
| Ex. 1 | Silica | 5.0 | 0.015 | 0.03 | 0.6 | Glycine | 0.043 | 2.5 | 10.7 |
| Ex. 2 | Silica | 5.0 | 0.015 | 0.05 | 0.6 | Glycine | 0.043 | 2.5 | 17.9 |
| Ex. 3 | Silica | 5.0 | 0.015 | 0.07 | 0.6 | Glycine | 0.043 | 2.5 | 25.0 |
| Ex. 4 | Silica | 5.0 | 0.015 | 0.1 | 0.6 | Glycine | 0.043 | 2.5 | 35.8 |
| Ex. 5 | Silica | 5.0 | 0.015 | 0.15 | 0.6 | Glycine | 0.043 | 2.5 | 71.5 |
| Ex. 6 | Silica | 5.0 | 0.015 | 0.2 | 0.6 | Glycine | 0.043 | 2.5 | 107.3 |
| Comp. | Silica | 5.0 | 0 | 0 | 0.6 | Glycine | 0.043 | 2.5 | 0.0 |
| Ex. 1 | | | | | | | | | |
| Comp. | Silica | 5.0 | 0.015 | 0.001 | 0.6 | Glycine | 0.043 | 2.5 | 0.4 |
| Ex. 2 | | | | | | | | | |
| Comp. | Silica | 5.0 | 0.015 | 0.003 | 0.6 | Glycine | 0.043 | 2.5 | 1.1 |
| Ex. 3 | | | | | | | | | |
| Comp. | Silica | 5.0 | 0.015 | 0.005 | 0.6 | Glycine | 0.043 | 2.5 | 1.8 |
| Ex. 4 | | | | | | | | | |
| Comp. | Silica | 5.0 | 0.015 | 0.01 | 0.6 | Glycine | 0.043 | 2.5 | 3.6 |
| Ex. 5 | | | | | | | | | |

### (3) Evaluation of Stability of Hydrogen Peroxide

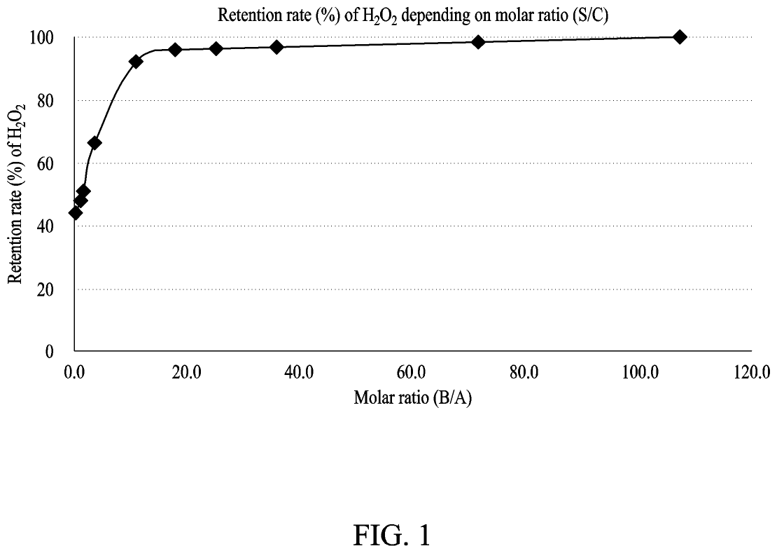

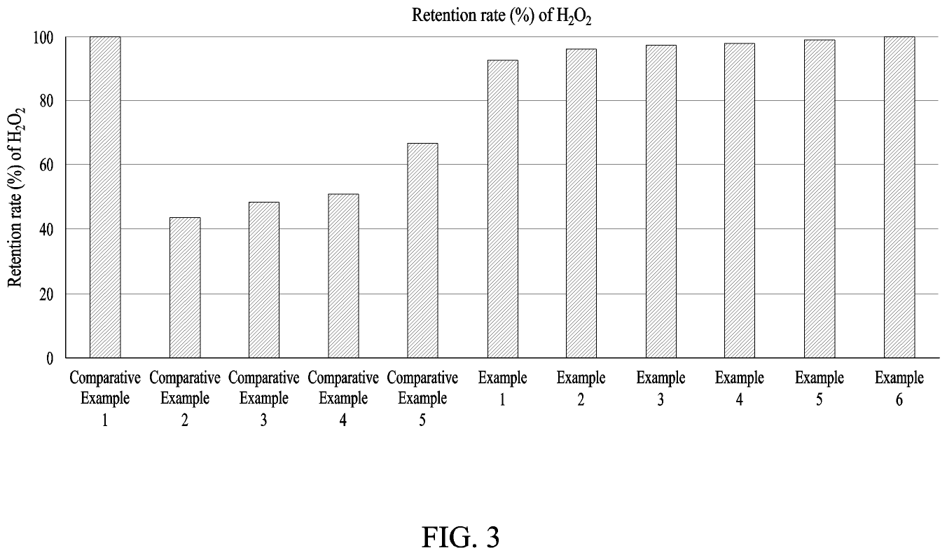

The retention rate (%) of hydrogen peroxide and the decomposition rate (%) of hydrogen peroxide were calculated for the slurry compositions of Examples 1 to 6 and Comparative Examples 1 to 5 according to the following equations, and the results are shown in Table 2, FIG. 1 and FIG. 3. The relationship between the molar ratio (B/A) described in Table 1 and the decomposition rate (%) of hydrogen peroxide is shown in FIG. 1.

From Table 2 and FIG. 1, it may be seen that the polishing slurry compositions of Examples 1 to 6 exhibit remarkably higher retention rate of hydrogen peroxide as compared to Comparative Examples 1 to 5. That is to say, it may be seen that the stability of hydrogen peroxide is improved when the ratio of hydrogen peroxide to malonic acid is 5 or greater or increases.

### Equations

Retention rate (%) of hydrogen peroxide=[concentration (%) of hydrogen peroxide after 7 days at room temperature×100]/[initial concentration (%) of hydrogen peroxide after addition to slurry composition]

Decomposition rate (%) of hydrogen peroxide=[(initial concentration (%) of hydrogen peroxide after addition to slurry composition−concentration (%) of hydrogen peroxide after 7 days at room temperature)×100]/[initial concentration (%) of hydrogen peroxide after addition to slurry composition]

### (4) Evaluation of Polishing Characteristics

A substrate including a tungsten film was polished with the polishing slurry compositions of Examples 1 to 6 and Comparative Examples 1 to 5 under the following polishing conditions.

[Polishing Conditions]

1. Polisher: KCT's ST-01

2. Wafer: Tungsten film wafer, 15 cm×15 cm

3. Platen pressure: 2 psi

4. Spindle speed: 87 rpm

5. Platen speed: 93 rpm

6. Flow rate: 250 mL/min

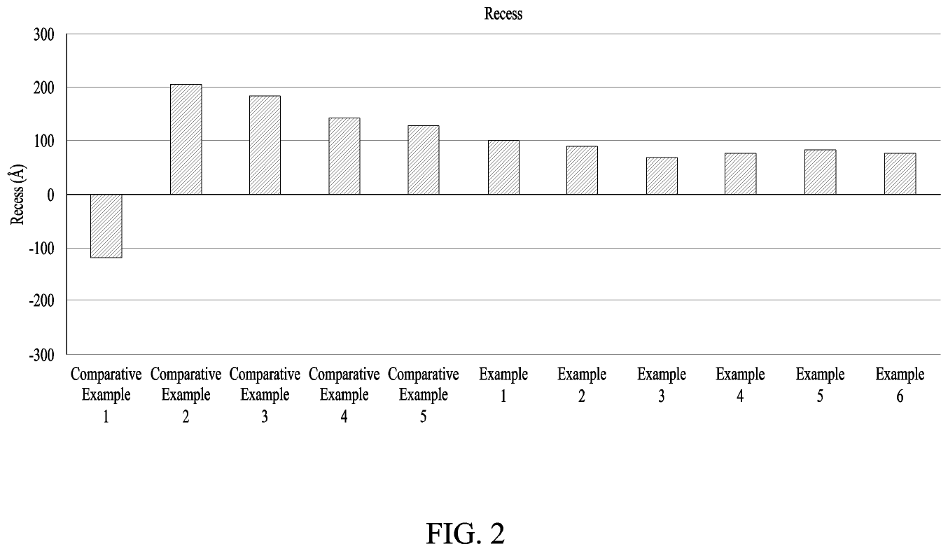

For evaluation of polishing characteristics, polishing speed and the depth of recesses on the patterned surface of the tungsten film substrate after polishing with the polishing slurry compositions of Examples 1 to 6 and Comparative Examples 1 to 5 were measured. The results are shown in Table 2 and FIG. 2.

TABLE 2

| | Decomposition | Retention | | |
|---|---|---|---|---|
| | rate (%) | rate (%) of | | |
| | of hydrogen | hydrogen | WRR | |
| | peroxide | peroxide | (Å/min) | Recess (Å) |
| Ex. 1 | 7.5 | 71.8 | 806 | 70 |
| Ex. 2 | 3.7 | 74.9 | 754 | 89 |
| Ex. 3 | 3 | 78.1 | 701 | 67 |
| Ex. 4 | 2.5 | 82.8 | 665 | 73 |
| Ex. 5 | 1.2 | 90.7 | 617 | 82 |
| Ex. 6 | 0.2 | 98.6 | 604 | 73 |
| Comp. Ex. | 0.2 | 99.8 | 326 | −120 |
| 1 | | | | |
| Comp. Ex. | 56.2 | 67.2 | 1016 | 205 |
| 2 | | | | |
| Comp. Ex. | 51.7 | 67.5 | 984 | 184 |
| 3 | | | | |
| Comp. Ex. | 48.9 | 67.8 | 925 | 142 |
| 4 | | | | |
| Comp. Ex. | 33.7 | 68.6 | 903 | 129 |
| 5 | | | | |

From Table 2, it may be seen that the polishing slurry compositions of Examples 1 to 6 may improve patterning characteristics by reducing recession phenomena after the polishing process while maintaining an appropriate polishing speed for the tungsten film. Although the slurry composition of Comparative Example 1, wherein iron nitrate and malonic acid were not added, exhibited high decomposition rate and retention rate of hydrogen peroxide, it was difficult to maintain good patterning characteristics due to increased recess depth caused by overpolishing and planarization defects were observed.

According to example embodiments, a polishing slurry composition, which maintains the stability of hydrogen peroxide and contains an iron-containing catalyst and a stabilizer at a specific ratio, may ensure polishing reproducibility in a continuous polishing process while achieving desired polishing performance (e.g., a polishing rate) for a polishing target film and may maintain good patterning characteristics by achieving planarization and by preventing an occurrence of a phenomenon (e.g., recess or erosion).

Although the example embodiments have been described by the examples and drawings, those having ordinary knowledge in the art may apply various modifications and alternations from the above description. For example, appropriate results may be achieved even when the described techniques are carried out in a different order from the above description and/or when the described elements are combined in different forms, or replaced or substituted with other elements or equivalents. Therefore, other example embodiments, examples and equivalents to patent claims belong to the scope of the patent claims described below.

What is claimed is:

1. A polishing slurry composition comprising:
abrasive particles;
an oxidizer;
an iron-containing catalyst; and
a stabilizer,
wherein a retention rate of the oxidizer according to Equation 1 is 70% or greater:
Retention rate (%) of oxidizer=(concentration (%) of oxidizer after 7 days at room temperature×100)/(initial concentration (%) of oxidizer in polishing slurry composition). [Equation 1]

2. The polishing slurry composition of claim 1, wherein a molar ratio of the stabilizer to the iron-containing catalyst is from 5:1 to 200:1.

3. The polishing slurry composition of claim 1, wherein the polishing slurry composition satisfies Equation 2:
99.8−2186×(amount (% by weight (wt %)) of iron-containing catalyst in polishing slurry composition)+158×(amount (wt %) of stabilizer in polishing slurry composition)>70. [Equation 2]

4. The polishing slurry composition of claim 1, wherein the iron-containing catalyst is included in an amount of 0.0001 wt % to 1 wt % in the polishing slurry composition.

5. The polishing slurry composition of claim 1, wherein
the iron-containing catalyst comprises an iron(II) compound, an iron(I) compound or both, and
the iron-containing catalyst comprises at least one selected from a group consisting of iron nitrate, iron sulfate, iron halide, iron perchlorate, iron acetate, iron acetylacetonate, iron gluconate, iron oxalate, iron phthalate and iron succinate.

6. The polishing slurry composition of claim 1, wherein
the stabilizer comprises an organic acid, and
the organic acid comprises at least one selected from a group consisting of citric acid, malic acid, maleic acid, malonic acid, oxalic acid, succinic acid, lactic acid, tartaric acid, adipic acid, pimelic acid, suberic acid, azelaic acid, sebacic acid, fumaric acid, acetic acid, butyric acid, capric acid, caproic acid, caprylic acid, glutaric acid, glycolic acid, formic acid, lauric acid, myristic acid, palmitic acid, phthalic acid, propionic acid, pyruvic acid, stearic acid, valeric acid and ascorbic acid.

7. The polishing slurry composition of claim 1, wherein the stabilizer is included in an amount of 0.0001 wt % to 1 wt % in the polishing slurry composition.

8. The polishing slurry composition of claim 1, wherein
the abrasive particles comprise at least one selected from a group consisting of a metal oxide, a metal oxide coated with an organic material or an inorganic material and a metal oxide in a colloidal phase, and
the metal oxide comprises at least one selected from a group consisting of silica, ceria, zirconia, alumina, titania, barium titanate, germania, mangania and magnesia.

9. The polishing slurry composition of claim 1, wherein the abrasive particles comprise single-sized particles with a size of 10 nanometers (nm) to 200 nm, or a mixture of two or more particles with different sizes of 10 nm to 200 nm.

10. The polishing slurry composition of claim 1, wherein the abrasive particles are included in an amount of 0.0001 wt % to 10 wt % in the polishing slurry composition.

11. The polishing slurry composition of claim 1, wherein the oxidizer comprises at least one selected from a group consisting of hydrogen peroxide, urea hydrogen peroxide, urea, percarbonate, periodic acid, periodate, perchloric acid, perchlorate, perbromic acid, perbromate, perboric acid, perborate, potassium permanganate, sodium perborate, permanganic acid, permanganate, persulfate, bromate, chlorite, chlorate, chromate, dichromate, chromium compound, iodate, iodic acid, ammonium peroxysulfate, benzoyl peroxide, calcium peroxide, barium peroxide, sodium peroxide, dioxygenyl, ozone, ozonide, nitrate, hypochlorite, hypohalite, chromium trioxide, pyridinium chlorochromate, nitrous oxide, monopersulfate, dipersulfate and sodium peroxide.

12. The polishing slurry composition of claim 11, wherein the oxidizer is included in an amount of 0.0001 wt % to 5 wt % in the polishing slurry composition.

13. The polishing slurry composition of claim 1, wherein
a polishing target film of the polishing slurry composition is a metal film, and
the metal film comprises at least one selected from a group consisting of a metal, a metal nitride, a metal oxide and a metal alloy.

14. The polishing slurry composition of claim 13, wherein each of the metal, the metal nitride, the metal oxide and the metal alloy comprises at least one selected from a group consisting of indium (In), tin (Sn), silicon (Si), titanium (Ti), vanadium (V), gadolinium (Gd), gallium (Ga), manganese (Mn), iron (Fe), cobalt (Co), copper (Cu), zinc (Zn), zirconium (Zr), hafnium (Hf), aluminum (Al), niobium (Nb), nickel (Ni), chromium (Cr), molybdenum (Mo), tantalum (Ta), ruthenium (Ru) and tungsten (W).

15. The polishing slurry composition of claim 1, further comprising a polishing inhibitor,
wherein the polishing inhibitor is included in an amount of 0.0001 wt % to 1 wt % in the polishing slurry composition.

16. The polishing slurry composition of claim 1, wherein the polishing inhibitor comprises at least one selected from a group consisting of glycine, histidine, alanine, serine, phenylalanine, threonine, valine, leucine, isoleucine, proline, lysine, arginine, aspartic acid, tryptophan, betaine, cocamidopropyl betaine, lauryl propyl betaine, methionine, cysteine, glutamine and tyrosine.

17. The polishing slurry composition of claim 1, wherein pH of the polishing slurry composition is in a range from 1 to 12.

18. The polishing slurry composition of claim 1, wherein a polishing speed of the polishing slurry composition for a polishing target film is 500 Å/min or greater.

19. The polishing slurry composition of claim 1, wherein a decomposition rate of the oxidizer according to Equation 3 is 10% or less:
Decomposition rate of oxidizer=(initial concentration (%) of oxidizer in polishing slurry composition−concentration (%) of oxidizer after 7 days at room temperature)×100/(initial concentration (%) of oxidizer in polishing slurry composition). [Equation 3]
